(19) United States
(12) Patent Application Publication
(10) Pub. No.: US 2013/0294018 A1
(43) Pub. Date: Nov. 7, 2013

(54) CABLE HOLDER AND DISPLAY DEVICE PROVIDED WITH CABLE HOLDER

(71) Applicants: Yoshihito Mochizuki, Tokyo (JP); Hsi-ming Chen, Tokyo (JP)

(72) Inventors: Yoshihito Mochizuki, Tokyo (JP); Hsi-ming Chen, Tokyo (JP)

(73) Assignee: NEC Display Solutions Ltd, Tokyo (JP)

(21) Appl. No.: 13/880,696

(22) PCT Filed: Oct. 22, 2010
(86) PCT No.: PCT/JP2010/068739

§ 371 Date: Jul. 22, 2013

(51) Int. Cl. F16L 3/06; H05K 7/02

(52) U.S. Cl. CPC F16L 3/06; H05K 7/02
USPC 361/679.01; 248/49

(57) ABSTRACT

A cable holder includes a holder body, and first and second arm sections that extend from the holder body, and extend in mutually approaching, intersecting directions so as to enclose a housing space for housing a cable. The first arm section has a first oblique section at a tip part thereof, and the second arm section has a second oblique section at a tip part thereof. The first and second oblique sections are inclined in mutually reverse directions, face each other, and are arranged with a gap therebetween.

### TECHNICAL FIELD

The present invention relates to a cable holder that supports various cables used for various display devices such as a liquid crystal display and other devices, and a display device includes this cable holder.

### BACKGROUND ART

In recent years, display devices among which liquid crystal displays, plasma displays, and the like are representative, have become widespread as display devices including displays, such as personal computers, TV sets, and the like. Among these display devices those whose display is supported by a rising/falling stand that can rise and fall. This rising/falling stand that can rise and fall, includes a height adjustment mechanism whereby the vertical position of the display can be adjusted to suit the eye height of the viewer.

As a display device including such a rising/falling stand that can rise and fall, there is one in which a rising/falling stand is attached to the display of a personal computer. For example, in a display device disclosed in Patent Document 1, as a rising/falling stand, a rising/falling member provided with a display is inserted into a guide member supported by a base section, such that it can rise and fall.

The guide member and the rising/falling member are both formed with approximately rectangular cross-sections, and there is a friction mechanism using a one-way clutch between the two members.

Furthermore, as a display device with a fixed type stand that does not rise and fall, there is one disclosed in Patent Document 2 for example. In this device, a stand projects upward from a computer body provided underneath, and the display is supported on the top.

Among the above-described display devices, many of those provided with a rising/falling stand as in Patent Document 1 have various cables, such as a power cable connected to the display from a power source, an image cable through which image information is transmitted, cables for USB or video, and the like, connected to the display from outside. On the other hand, many of those provided with a fixed stand as in Patent Document 2, have cables extending through the stand to the display.

### PRIOR ART DOCUMENTS

### Patent Documents

[Patent Document 1] Japanese Unexamined Patent Application, First Publication No. 2005-300922

[Patent Document 2] Japanese Unexamined Patent Application, First Publication No. H08-328694

### SUMMARY OF THE INVENTION

### Problem to be Solved by the Invention

In the above-described display devices, for those in which various cables are disposed outside of the display or stand, when pivoting the display in the horizontal direction or the vertical direction, or in the horizontal and vertical directions, or when raising or lowering, the cables are sometimes pulled or twisted. Moreover, a number of the cables connected to the display are wired such that they spread over the floor or the like. Therefore the occupied space is large, so that they can be tripped over, which is an obstacle, and also unsightly.

The present invention takes the above problems into consideration, and has an object of providing a cable holder that can support various cables so that they do not become obstacles, and a display device including this cable holder.

### Means for Solving the Problem

A cable holder according to the present invention includes a pair of arm sections that extend from a holder body and extend in mutually approaching, intersecting directions to enclose a housing space for housing a cable, respective tip sections of the first arm section and the second arm section are formed with a first oblique section and a second oblique section, which are inclined in reverse directions, facing each other, and a gap is formed between the first oblique section and second oblique section.

According to the present invention, in the case where cables are inserted into or removed from the housing space, it is possible to insert or remove them through the gap by elastically defaulting at least one of the first oblique section and the second oblique section of the pair of arm sections. The cables make contact with either one of the pair of arm sections to be locked in a state in which they are retained in the housing space so that they do not fall out.

Furthermore, it is preferable that each of the first oblique section of the first arm section and the second oblique section of the second arm section is provided with a bump protruding into the gap, and the bump of the first oblique section and the bump of the second oblique section are provided such that they are dislocated in a direction in which the gap extends.

Even if the cables housed in the housing space tend to fall out of the gap between the pair of arm sections, it is possible to prevent them from falling out by making contact with the bumps.

Moreover, it is preferable that a distance between the bump of the first oblique section and the bump of the second oblique section is set to be smaller than an outer diameter of the cable.

As a result, the cables retained in the housing space do not fall out of the gap accidentally.

Furthermore, the first oblique section provided at the tip part of the first arm section and the second oblique section provided at the tip part of the second arm section may be formed such that widths gradually become smaller toward a tip.

If the tips of the first arm section and the second arm section are tapered, they will elastically deform easily toward the ends of the tips, so that it is easy to insert or remove the cables.

In a display device according to the present invention, a display is provided on a stand supported by a base member, and any one of the above-described cable holders is attached to a support section, which is rotatably provided at a top part of the stand, and supports the display.

By attaching the cable holder to the support section provided at the top part of the stand, the cables can be housed in the housing space by the pair of arm sections, making contact with the arm sections so that they can be locked and not fall out. Moreover, in the case where the cables are inserted into or removed from the housing space, it is possible to insert or remove them through the gap by deforming at least one of the first oblique section and the second oblique section of the pair of arm sections.

Moreover, it is preferable that the holder body of the cable holder is provided with an engaging part, which can be attached and detached, for engaging with the top part of the stand.

When mounting the cable holder on the support section of the top part of the stand of the display device, it can be mounted by engaging the engaging part with the support section.

### Effect of the Invention

As described above, according to a cable holder, and a display device including the cable holder, of the present invention, in a state in which various cables such as a power cable, an image cable, and the like, are housed in the housing space, even if there is a gap, it is possible to retain the cables by the first arm section and the second arm section. Furthermore, in the case where various cables are housed in or removed from the housing space, the cables are inserted through the gap between the first oblique section and the second oblique section of the pair of the arm sections, causing at least one of the arm sections to elastically deform to expand the gap, enabling insertion and removal.

Moreover, according to a display device including a cable holder of the present invention, in the case where the display is pivoted in the horizontal direction or the vertical direction, or the orientation between the horizontal and vertical directions is switched, or in the case where the display is raised or lowered, various cables engaged in the cable holder also rotate, rise, or fall following the display in a location close to the display, so that a large load on the joint with the display, due to the cables being pulled or twisted by the display, is restricted. Furthermore, in a state in which the display is lowered, the cables do not spread over the desk, the floor, or the like, to become an obstacle.

In contrast with this, in the case where a cable holder for retaining cables is not attached to the support section, deficiencies occur in that when the display is rotated or raised, the cables are pulled by the joint with the display, or twisted, generating a load, and when the display is lowered, the cables scatter in the neighborhood in a slackened state, which becomes an obstacle.

### BRIEF DESCRIPTION OF THE DRAWINGS

FIG. 1 is a perspective view showing a state in which a cable holder is mounted on the supporting section of a rising/falling stand of a display device, according to a first exemplary embodiment of the present invention.

FIG. 2 is a perspective view showing a state in which the cable holder is separated from the support section of the display device shown in FIG. 1.

FIG. 3 is an enlarged perspective view of a main part, which shows a state in which the cable holder is mounted on the support section shown in FIG. 1.

FIG. 4A is a perspective view of the cable holder viewed from an arm side.

FIG. 4B is a front view of the cable holder viewed from an arm section side.

FIG. 5A is a perspective view of the cable holder viewed from an opening section side.

FIG. 5B is a perspective view of the cable holder shown in FIG. 5B inverted.

FIG. 6 is a perspective view of a main part in a state in which a power cable and an image cable are housed in a housing space of the cable holder.

FIG. 7 is a perspective view showing a cable holder according to a second exemplary embodiment of the present invention.

FIG. 8 is a front view of the cable holder shown in FIG. 7 viewed from an arm section side.

### EMBODIMENTS FOR CARRYING OUT THE INVENTION

Hereunder is a description of cable holders and display devices including the cable holders according to exemplary embodiments of the present invention, with reference to the appended drawings.

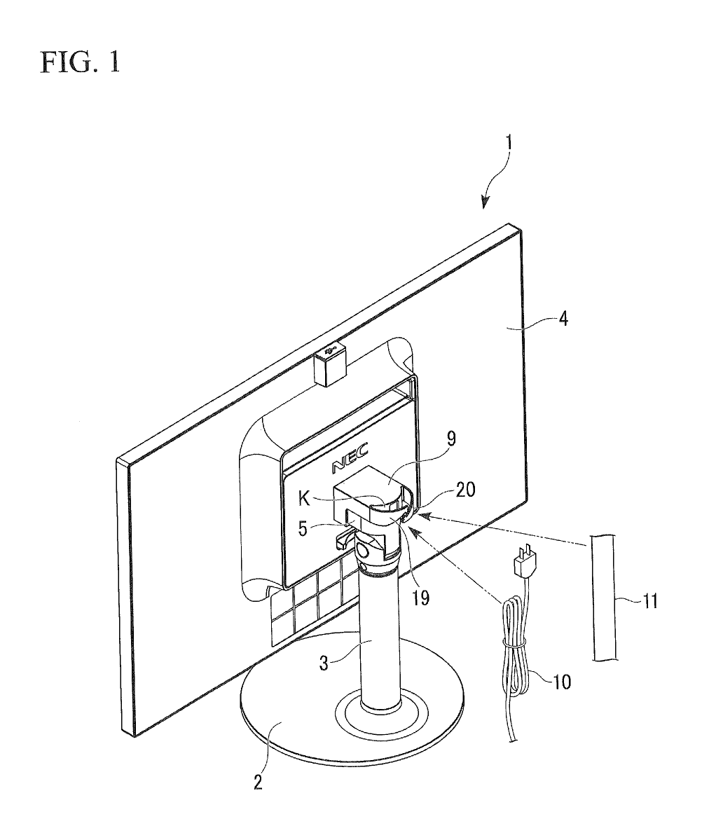

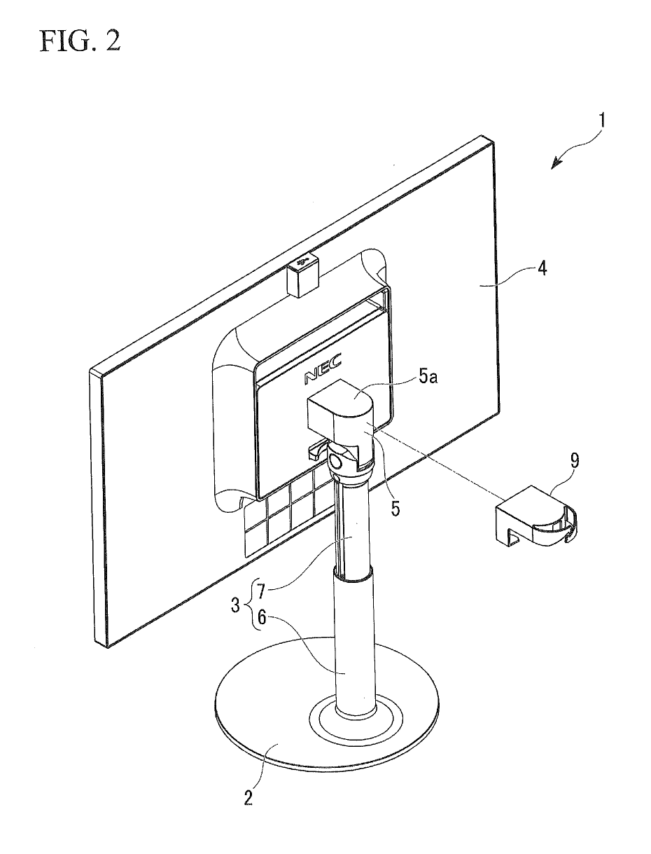

As shown in FIG. 1 and FIG. 2, in a display device 1, a rising/falling stand 3 that can rise and fall is attached to a platform-like base member 2, and a display 4 such as a liquid crystal display and a support section 5 therefor are attached to the top part of the rising/falling stand 3.

The rising/falling stand 3 is constituted from a fixed support column 6 fixed to the base member 2, and a rising/falling support column 7 that can rise and fall with respect to the fixed support column 6, and the fixed support column 6 and the rising/falling support column 7 are formed approximately cylindrically, for example.

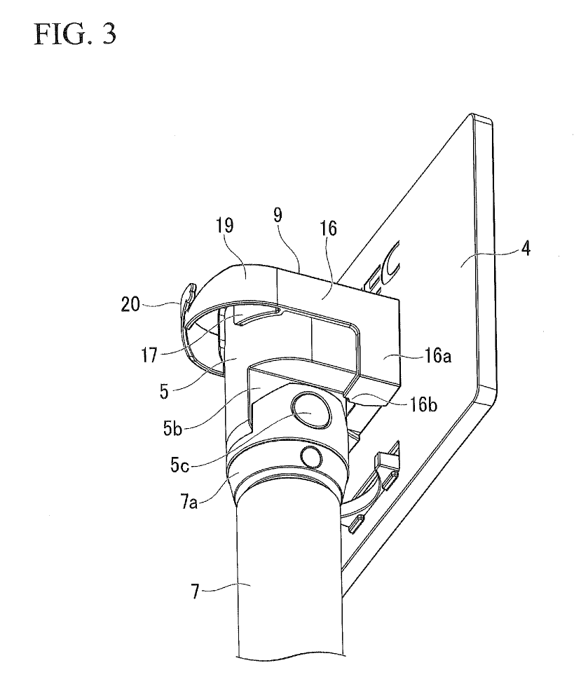

In FIG. 3, the display 4 is fixed to the support section 5 provided at the top end of the rising/falling support column 7, and a lower part 5b of the support section 5 is substantially plate shape foaming a parallel plate. The support section 5 can pivot integrally with the display 4 in the vertical direction about a central shaft part 5c with respect to the rising/falling stand 3, and can rotate horizontally with respect to a seat part 7a provided on the rising/falling support column 7. Furthermore, the display 4 having a rectangular shape is arranged such that it can rotate in the vertical plane with respect to the support section 5 so that the longitudinal direction can be switched between the horizontal orientation and the vertical orientation.

Furthermore, a top part 5a of the support section 5 of the display device 1 is formed as a plane for example, and the cable holder 9 is attached to the top part 5a such that it can be attached and removed. Various cables such as a power cable 10 for supplying current to the display 4, an image cable 11, and also a USB cable, a video cable, and the like can be attached to the cable holder 9.

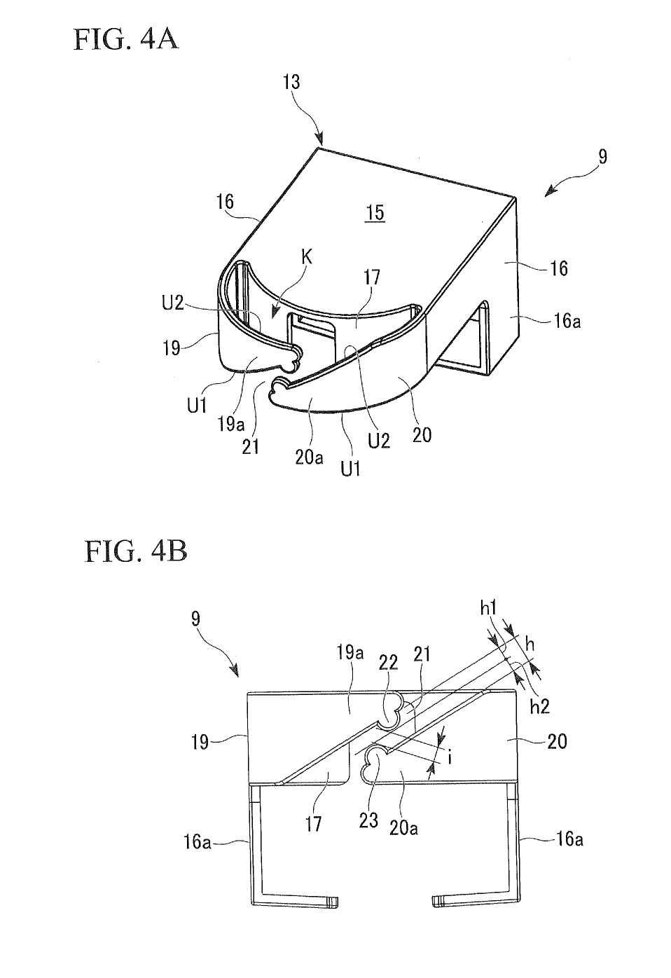

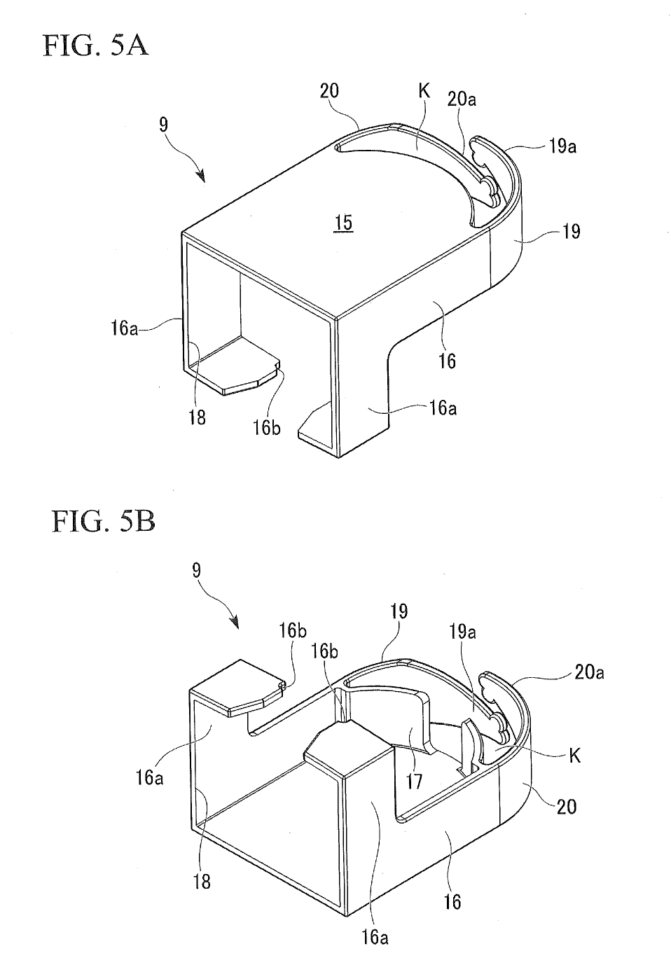

Next is a description of the structure of the cable holder 9 with reference to FIG. 4A, FIG. 4B, FIG. 5A, and FIG. 5B.

In the cable holder 9 in the present description, the region in which cables 10 and 11 are retained is defined as the front part, or front, and the opposite side is defined as the rear part, or rear.

In FIG. 4A, FIG. 4B, FIG. 5A, and FIG. 5B, the cable holder 9 includes a holder body 13, and arm sections 19 and 20. Regarding the holder body 13, a pair of approximately L-shaped side sections 16 extend in the approximately vertical direction from the two side parts of a flat plate shape section 15 having a flat plat shape, leg sections 16a formed at the rear end part of the approximately L-shaped side section 16 are bent inwards, and engaging hook parts 16b are formed at the tip corners. Furthermore, the support section 5 can be inserted into an opening 18, having a square shape for example, formed by the plane section 15 and the leg sections 16a.

An approximately arc shaped partition wall 17 is formed on the front side of the plane section 15, approximately arc shaped arm sections 19 and 20 extend from the side sections 16 provided on the two sides of the partition wall 17, and the ends of the arm sections 19 and 20 extend so as to partially overlap without touching each other when viewed in the vertical direction. The space between the arm sections 19 and 20 and the partition walls 17 constitutes a housing space K for cables.

The two arm sections 19 and 20 are both formed a little longer than approximately a quarter of a circle in plan view, and the tip sections are formed in the same approximately arc shaped plane, so as to overlap without touching.

The first arm section 19 is formed with a constant width from one side section 16 to the neighborhood of the tip extending in an approximately arc shape, and an upper oblique section 19a having an approximately triangular shape is formed in the neighborhood of the tip as a first oblique section with a lower edge part u1 inclined toward an upper edge part u2 to make the width become gradually smaller. The second arm section 20 is formed with a constant width from the other side section 16 to the neighborhood of the tip extending in an approximately arc shape, and a lower oblique section 20a having an approximately triangular shape is formed in the neighborhood of the tip as a second oblique section with an upper edge part u2 inclined toward a lower edge part u1 to make the width become gradually smaller.

The free ends of the arm sections 19 and 20 are the tapered upper oblique section 19a and lower oblique section 20a, and can be elastically deformed.

In FIG. 4B, a gap 21 with an approximately constant width h is formed between the upper oblique section 19a and the lower oblique section 20a. In the neighborhood of the tip of the upper oblique section 19a, an approximately semicircular bump 22 is formed, for example, so as to protrude from the lower edge part u1 into the gap 21, and in the neighborhood of the tip of the lower oblique section 20a, an approximately semicircular bump 23 is formed, for example, so as to protrude from the upper edge part u2 into the gap 21. The two bumps 22 and 23 are dislocated in the direction in which the gap 21 extends.

In FIG. 4B, in the case where the extent of the protrusion of the bump 22 is designated h1, and the extent of the protrusion of the bump 23 is designated h2 when viewed in the extending direction of the gap 21, the width of the gap 21 h is set approximately h1+h2. Preferably, h1=h2. Moreover, with the gap between any tangential lines of the bump 22 and the bump 23 designated i, the gap i is set smaller than the smallest diameter among one or a plurality of kinds of cables 10 and 11 housed in the housing space K, for example the outer diameter of the power cable 10.

Therefore, when the power cable 10, the image cable 11, and the like are inserted into the gap 21 of the arm sections 19 and 20, the upper oblique section 19a or the lower oblique section 20a is elastically deformed to expand the width of the gap 21, so that the power cable 10, the image cable 11, and the like can be inserted and retained in the housing space K.

The cable holder 9 and the display device 1 including the same according to the present exemplary embodiment have the above-described construction. Next is a description of a method for mounting and a method for using the cable holder 9.

Firstly, in the case where the cable holder 9 is fitted onto the support section 5 of the display device 1, when the opening section 18 provided at the rear part of the cable holder 9 is fitted onto a part of the support section 5 on the opposite side to the display 4, the cable holder 9 is fitted with the flat surface 15 being guided by the top part 5a of the support section 5. Then, when the opening section 18 of the cable holder 9 makes contact with the display 4, the engaging hook parts 16b provided on the leg sections 16a of the cable holder 9 are pressed by the corner parts formed on the lower part 5b of the support section 5, and the leg sections 16a are elastically deformed so that the engaging hook parts 16b are engaged onto the corner parts. As a result, the cable holder 9 is engaged and retained such that it covers the support section 5.

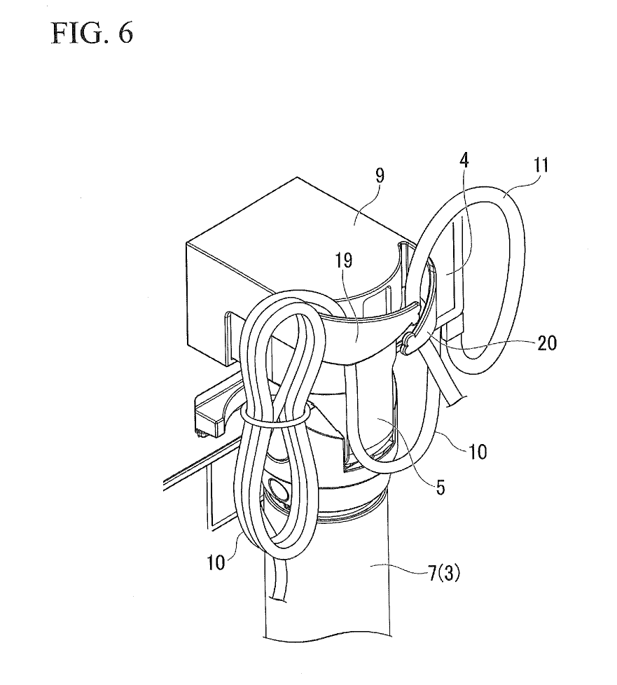

In this state, the power cable 10, which has one end connected to a power source and a connector on the other end inserted into the display 4, is inserted into the gap 21 between the arm sections 19 and 20 of the cable holder 9. By so doing, as shown in FIG. 6, by the upper oblique section 19a and/or the lower oblique section 20a being elastically deformed to expand the width of the gap 21, the power cable 10 is inserted into the housing space K, locked by the arm sections 19 and 20, and retained. Other cables such as the image cable 11, a USB cable, or the like are similarly inserted into and retained in the housing space K.

Moreover, in the case where the display device 1 is rotated horizontally or its angle in the vertical direction is adjusted, or the longitudinal direction of the display 4 is rotated to switch between the horizontal orientation and the vertical orientation, even if cables such as the power cable 10, the image cable 11, and the like move in the housing space K due to their momentum, they are retained in a state in which they make contact with the arm sections 19 and 20. Furthermore, even if the power cable 10, the image cable 11, or the like falls into the gap 21 between the arm sections 19 and 20, since the gap i between the bumps 22 and 23 is smaller than the outside diameter of the cables 10, 11, or the like, the cable is locked by the bumps 22 and 23, so that it can be prevented from falling out of the ann sections 19 and 20.

On the other hand, in the case where the power cable 10, the image cable 11, or the like retained in the housing space K is removed, if the power cable 10 or the image cable 11 is moved into the gap 21, and pulled to the outside, the section 19 and/or the arm section 20 is elastically deformed, enlarging the gap 21, so that they can be removed.

Furthermore, even in the case where the display 4 is rotated horizontally or its angle is adjusted, or is rotated to switch between the horizontal and vertical orientations as described above, since the power cable 10, the image cable 11, and the like are supported by the cable holder 9 mounted onto the support section 5 in the neighborhood of the rear surface of the display 4, the power cable 10, the image cable 11, and the like follow without being twisted or pulled.

Moreover, when the display 4 is moved vertically by raising or lowering the rising/falling stand 3, the support section 5 and the cable holder 9 move vertically together as one, and the power cable 10, the image cable 11, and the like supported by the cable holder 9 also move vertically, so that the cables are not twisted or pulled at the joint with the display 4.

As described above, according to the cable holder 9 of the present exemplary embodiment, in a state in which cables such as the power cable 10, the image cable 11, and the like are housed in the housing space K, the cables make contact with the arm sections 19 and 20 or the upper oblique section 19a and lower oblique section 20 thereof, and are retained. Furthermore, even if the cables enter the gap 21, since the gap i between the bumps 22 and 23 is smaller than the outer diameter of the cables, it is possible to prevent them from falling out.

Moreover, in the case where the abovementioned cables are housed in or removed from the housing space K, the cables are inserted into the gap 21 between the upper oblique section 19a and the lower oblique section 20a of the arm sections 19 and 20, and by pressing them in or pulling them out, at least one of the arm sections 19 and 20 is elastically deformed, expanding the gap 21, which enables insertion or removal.

Furthermore, in the case where cables such as the power cable 10, the image cable 11, and the like are housed in the housing space K of the cable holder 9 provided on the support section 5 of the display device 1, when the rising/falling stand 3 is raised or lowered, or when the height or the orientation of the display 4 is adjusted by rotating it in the horizontal direction or the vertical direction, or in the horizontal and vertical orientations, the various cables retained in the cable holder 9 also rise or fall, or rotate together with the support section 5 and the display 4. Therefore, the cables are not pulled or twisted by the display 4. Furthermore, in a state in which the rising/falling stand 3 is lowered, the cables do not spread out over the desk, the floor, or the like, to become an obstacle.

In contrast with this, in the case where the cable holder 9 for housing cables is not mounted on the support section 5, deficiencies occur in that when the display 4 is rotated or raised, the cables are pulled directly by the joint with the display 4, and when the display is lowered, the cables scatter in the neighborhood in a state of being slackened and spread out, which becomes an obstacle.

The present invention is not limited to the above-described embodiment, and any appropriate change is possible within a range which does not depart from the scope thereof.

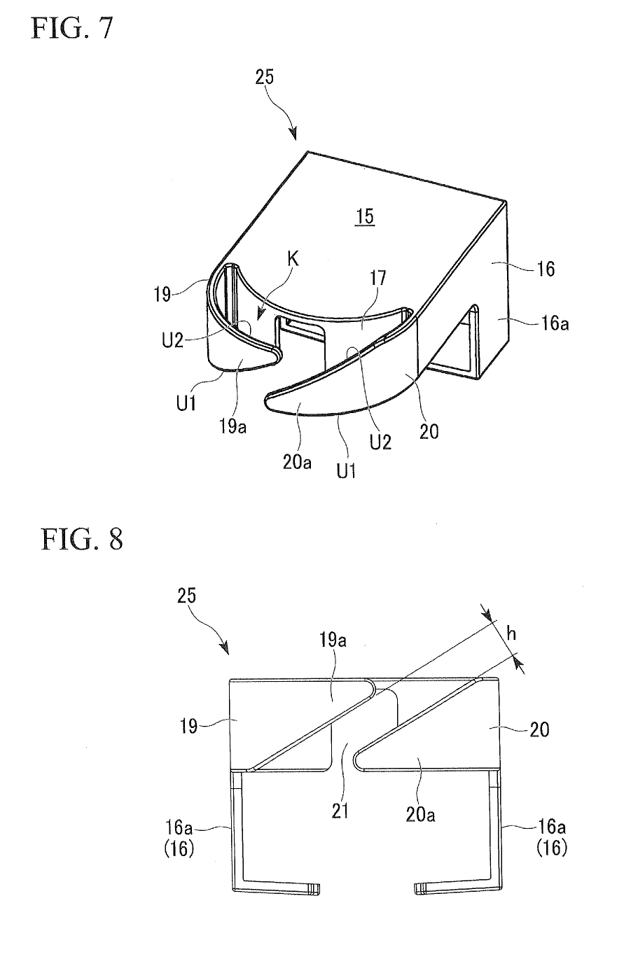

Next is a description of a cable holder 25 according to a second exemplary embodiment of the present invention, with reference to FIG. 7 and FIG. 8.

The cable holder 25 according to this second exemplary embodiment has substantially the same shape as the cable holder 9 according to the first exemplary embodiment. The point of difference is that there are no bumps 22 and 23 protruding into the gap 21 in the first arm section 19 and the second arm section 20.

In this case also, various cables such as the power cable 10, the image cable 11, and the like, retained in the housing space K, are locked by the arm sections 19 and 20, and retained. Even in the case where the various cables make contact with the upper edge part u2 constituting an inclined face, which is formed on the lower oblique section 20a of the other cable 20, they can be locked and retained by friction.

Alternatively, if the width h of the gap 21 in the second exemplary embodiment is set to be smaller than the outer diameter dimension of the power cable 10, being the smallest cable, it is possible to further prevent it from falling out accidentally. Even in this case, when cables are inserted into or removed from the housing space K, by elastically deforming the arm sections 19 and 20 to expand the gap 21, it is possible to insert and remove the cables easily.

Furthermore, in the above-described first exemplary embodiment, the bumps 22 and 23 provided on the first arm section 19 and the second arm section 20 are made approximately semicircular. However, the shape of the bumps 22 and 23 is not limited to semicircular, and they may be oblong, approximately triangular or an appropriate polygon, and any desired shape can be used.

Moreover, it is preferable that the first arm section 19 and the second arm section 20 are disposed such that the upper inclined face 19a and the lower inclined face 20a are close together with the gap 21 interposed such that they do not touch each other, but it is not essential that they do not touch. For example, the bumps 22 and 23 may touch each other, and the arm sections 19 and 20 may be elastically deformed by pressing the bumps 22 and 23 when inserting or removing the cables, so that the gap 21 can be enlarged.

### INDUSTRIAL APPLICABILITY

The present invention has an object of providing a cable holder which includes a pair of elastically deformable arm sections that extend from a holder body and extend in mutually intersecting directions in a manner so as to enclose a cable housing space. The respective tip sections of the first arm section and the second arm section are formed with a first oblique section and a second oblique section, which are inclined in reverse directions with the width narrowing, and face each other with a gap interposed, so that the cables can be retained by the pair of arm sections and also can be inserted into or removed from the housing space easily by elastically deforming the arm sections.

Furthermore, the present invention has an object of providing a display device including a cable holder that can prevent cables connected to a display from being pulled or slackened, wherein the cable holder is mounted on a support section at the top part of the stand of the display device, so that the cable holder follows even when the display is rotated, raised, or lowered.

### REFERENCE SYMBOLS

1 Display device
2 Base member
3 Rising/falling stand
4 Display
6 Fixed support column
7 Rising/falling support column
9, 25 Cable holder
13 Holder body
16 Side section
16a Leg section
16b Engaging hook part
19, 20 Ann section
19a Upper oblique section
20a Lower oblique section
21 Gap
22, 23 Bump

1. A cable holder comprising:
a holder body; and
first and second arm sections that extend from the holder body, and extend in mutually approaching, intersecting directions so as to enclose a housing space for housing a cable,
the first arm section having a first oblique section at a tip part thereof, and the second arm section having a second oblique section at a tip part thereof,
the first and second oblique sections inclined in mutually reverse directions, facing each other, and arranged with a gap therebetween.

2. The cable holder according to claim 1, wherein each of the first oblique section of the first arm section and the second oblique section of the second arm section is provided with a bump protruding into the gap, and the bump of the first oblique section and the bump of the second oblique section are provided such that the bumps are dislocated with each other in a direction in which the gap extends.

3. The cable holder according to claim 2, wherein a distance between the bump of the first oblique section and the bump of the second oblique section is set to be smaller than an outer diameter of the cable.

4. The cable holder according to claim 1, wherein a width of the first oblique section provided at the tip part of the first arm section is gradually become smaller toward a tip of the first oblique section, and a width of the second oblique section provided at the tip part of the second arm section is gradually become smaller toward a tip of the second oblique section.

5. A display device comprising:
a base member;
a stand supported by the base member;
a support section rotatably provided at a top part of the stand;
a display supported by the support section; and
the cable holder according to claim 1 attached to the support section.

6. The display device according to claim 5, wherein the holder body of the cable holder includes an engaging part configured to attach to and detach from the support section, and engaging with the support section.
